(19) United States
(12) Patent Application Publication
(10) Pub. No.: US 2026/0219336 A1
(43) Pub. Date: Jul. 30, 2026

(54) HIGH-PSSR DIFFERENTIAL FAST SWITCHING COIL DRIVER

(71) Applicant: Allegro MicroSystems, LLC, Manchester, NH (US)

(72) Inventor: Hernán D. Romero, Buenos Aires (AR)

(73) Assignee: Allegro MicroSystems, LLC, Manchester, NH (US)

(21) Appl. No.: 19/032,167

(22) Filed: Jan. 20, 2025

(51) Int. Cl. G01R 33/00; G01R 33/06

(52) U.S. Cl. CPC G01R 33/0029; G01R 33/0041; G01R 33/06

(57) ABSTRACT

A sensor, comprising: one or more magnetic field sensing elements that are configured to generate a sensing signal, the sensing signal being indicative of a strength of a magnetic field that is incident on the one or more magnetic field sensing elements; a processing circuitry that is configured to generate an output signal based on the sensing signal; and a first amplifier that is configured to drive a first coil based on the sensing signal, the first coil being coupled in a first negative feedback loop of the first amplifier, wherein the first negative feedback loop spans between a first input terminal of the first amplifier and a first output terminal of the first amplifier, and wherein the sensing signal is, at least in part, applied at the first input terminals of the first amplifier.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with proximity or motion of a target object. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: one or more magnetic field sensing elements that are configured to generate a sensing signal, the sensing signal being indicative of a strength of a magnetic field that is incident on the one or more magnetic field sensing elements; a processing circuitry that is configured to generate an output signal based on the sensing signal; and an amplifier that is configured to drive a first coil and a second coil based on the sensing signal, the first coil being coupled in a first negative feedback loop of the amplifier, and the second coil being coupled in a second negative feedback loop of the amplifier, wherein the first negative feedback loop spans between a first input terminal of the amplifier and a first output terminal of the amplifier, and the second negative feedback loop spans between a second input terminal of the amplifier and a second output terminal of the amplifier, and wherein the sensing signal is applied at the first and second input terminals of the amplifier.

According to aspects of the disclosure, sensor is provided, comprising: one or more magnetic field sensing elements that are configured to generate a sensing signal, the sensing signal being indicative of a strength of a magnetic field that is incident on the one or more magnetic field sensing elements; a processing circuitry that is configured to generate an output signal based on the sensing signal; and a first amplifier that is configured to drive a first coil based on the sensing signal, the first coil being coupled in a first negative feedback loop of the first amplifier, wherein the first negative feedback loop spans between a first input terminal of the first amplifier and a first output terminal of the first amplifier, and wherein the sensing signal is, at least in part, applied at the first input terminals of the first amplifier.

According to aspects of the disclosure, a sensor is provided, comprising: one or more magnetic field sensing elements that are configured to generate a sensing signal, the sensing signal being indicative of a strength of a magnetic field that is incident on the one or more magnetic field sensing elements; a processing circuitry that is configured to generate an output signal based on the sensing signal; and a first amplifier that is configured to drive a first coil based on the sensing signal, the first coil being coupled in a first negative feedback loop of the first amplifier, wherein the first negative feedback loop spans between a first input terminal of the first amplifier and a first output terminal of the first amplifier.

### BRIEF DESCRIPTION OF THE DRAWINGS

The foregoing features may be more fully understood from the following description of the drawings in which:

FIG. 1A is a diagram of an example of a sensor, according to the prior art;

FIG. 1B is a diagram of an example of a sensing bridge, according to the prior art.

FIG. 2 is a diagram of an example of a sensor, according to the prior art;

FIG. 3 is a diagram of an example of a coil driver, according to the prior art;

FIG. 4 is a diagram of an example of a coil driver, according to aspects of the disclosure;

FIG. 5 is a diagram of an example of a coil driver, according to aspects of the disclosure;

FIG. 6 is a diagram of an example of a coil driver, according to aspects of the disclosure;

FIG. 7A is a diagram of an example of a sensor, according to aspects of the disclosure;

FIG. 7B is a diagram of an example of a sensor, according to aspects of the disclosure;

FIG. 8 is a diagram of an example of a sensor, according to aspects of the disclosure;

FIG. 9A is a diagram of an example of a coil, according to aspects of the disclosure; and

FIG. 9B is a diagram of an example of a coil, according to aspects of the disclosure.

### DETAILED DESCRIPTION

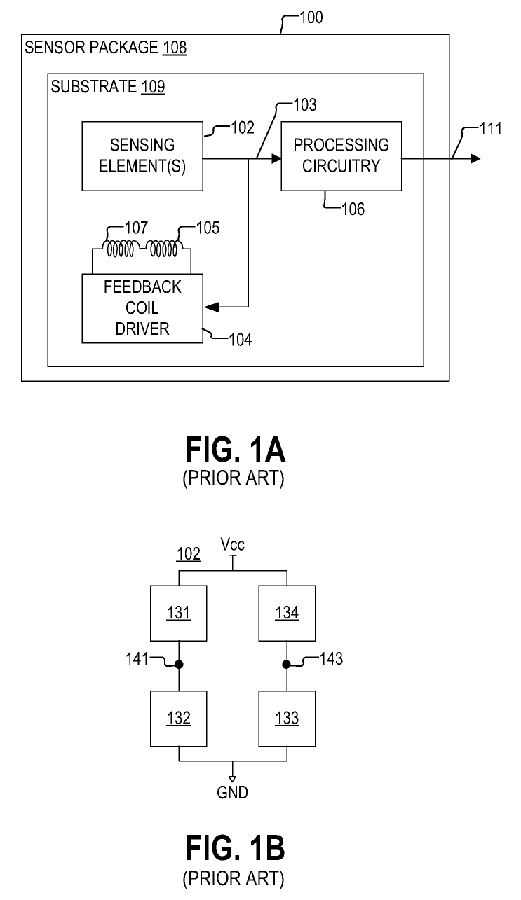

FIG. 1A is a diagram of a magnetic field sensor 100, according to the prior art. Sensor 100 may include a current sensor, a position sensor, and/or any other suitable type of magnetic field sensor. As illustrated, sensor 100 may include one or more sensing elements 102, a feedback coil driver 104, a processing circuitry 106, and feedback coils 105 and 107. According to the example of FIG. 1A, the sensing elements 102, the feedback coil driver 104, the feedback coils 105 and 107, and the processing circuitry 106 may be formed on a substrate 109 (e.g., a silicon substrate) and encapsulated inside a sensor package 108. Feedback coils 105 and 107 may be implemented by using conductive traces that are formed on the substrate 109. The sensor package 108 may be formed by using an epoxy resin, a silicon gel, and/or any other suitable type of encapsulating compound. The sensing elements 102 may include one or more magnetic field sensing elements 102, such as giant magnetoresistance (GMR) elements, tunneling magnetoresistance (TMR) sensing elements, Hall elements, fluxgate elements, and/or any other suitable type of magnetic field sensing elements. The processing circuitry 106 may include any suitable type of analog and/or digital circuitry for processing the output of sensing elements 102. By way of example, processing circuitry 106 may include one or more amplifiers, one or more digital-to-analog converters (DACs), one or more analog-to-digital converters (ADCs), one or more filters (analog or digital) and/or any other suitable processing circuitry that is normally found in magnetic field sensors. The feedback coils 105 and 107 may be connected in series as shown. The feedback coil driver 104 may include any suitable type of processing circuitry for driving feedback coils 105 and 107. The feedback coil 105 may be configured to subject some of the sensing elements 102 to a first feedback magnetic field that is generated by the feedback coil 105. The feedback coil 107 may be configured to subject the rest of the sensing elements 102 to a second magnetic field that is generated by feedback coil 107. The first and second feedback magnetic fields may be used to balance the sensitivity of sensing elements 102. The second magnetic field may be adapted to compensate for an external magnetic field that is incident on sensing elements 102, which in turn in would ideally force sensing elements 102 to work at zero gauss (or close to zero gauss) and have a stable sensitivity. In some implementations, sensor 100 may be configured in the manner discussed in U.S. Patent Application 18/922,607 entitled High Accuracy Sensor with Heterogeneous Architecture, and U.S. Patent Application 18/527,675 entitled Low Residual Offset Sensor, both of which are hereby incorporated by reference herein in their entirety.

FIG. 1B is a diagram of sensing elements 102, according to one example. In the example of FIG. 1B, sensing elements 102 includes magnetoresistance (MR) elements 131, 132, 133, and 134. In the example of FIG. 1B, feedback coil 105 may be positioned in greater proximity to some of the MR elements 131-134, and feedback coil 107 may be positioned in greater proximity to the remaining ones of the MR elements 131-134. In general, the first magnetic field (generated by coil 105) may affect only the MR elements which are positioned in greater proximity to feedback coil 105, while the remaining MR elements may be substantially (or completely) unaffected by the first magnetic field. Similarly, the second magnetic field (generated by coil 107) may affect only the MR elements which are positioned in greater proximity to feedback coil 107, while the remaining MR elements may be substantially (or completely) unaffected by the second magnetic field. Those of ordinary skill in the art will readily appreciate that the exact positioning and orientation of feedback coils 105 and 107 may depend on the respective pinning directions of MR elements 131-134. The pinning directions of MR elements 131-134 may vary depending on the application.

Returning to FIG. 1A, the sensing elements 102 may be configured to generate a sensing signal 103. The sensing signal 103 may be generated in response to a magnetic field sensed by the sensing elements 102. The sensing signal 103 may be indicative of the strength (e.g., magnetic flux density) of the magnetic field that is incident on sensing elements 102. When the one or more sensing elements 102 are implemented as the sensing bridge shown in FIG. 1B, the sensing signal 103 may be output on nodes 141 and 142 of the sensing bridge. The processing circuitry 106 may process signal 103 to generate an output signal 111. The output signal may be provided to electronic circuitry that is connected to the sensor 100. The output signal 111 may be generated in any suitable manner. In this regard, it will be understood that the present disclosure is not limited to any specific method for generating the output signal. For example, when sensor 100 is a current sensor, the output signal 111 may be indicative of the level of electrical current that is flowing through a conductor, and it may be generated by using any method that is known to be employed by current sensors.

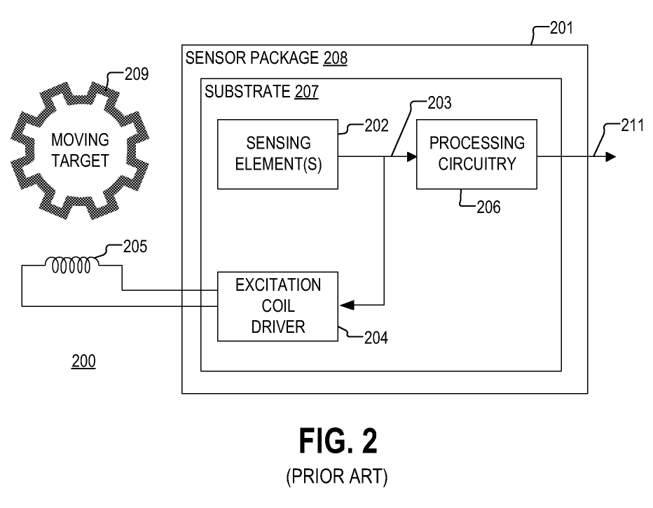

FIG. 2 is a diagram of an example of a system 200, according to the prior art. System 200 includes an excitation coil 205, a sensor 201, and a moving target 209. In the example of FIG. 2, sensor 201 is a position sensor that is configured to output an indication of the position of moving target 209. More specifically, sensor 201 may drive the excitation coil 205 to produce an excitation magnetic field. The excitation magnetic field may induce eddy currents in the moving target 209, which in turn may cause the moving target 209 to produce a magnetic field (hereinafter “reflected magnetic field”). The sensor 201 may sense the reflected magnetic field and output an indication of the position of moving target 209. Moving target 209 may be formed of metal and/or any other suitable type of magnetic material. Moving target 209 may be a gear, a linear target, and/or any other suitable type of target.

According to the example of FIG. 2, the sensing elements 202, the excitation coil driver 204, and the processing circuitry 206 may be formed on a substrate 207 (e.g., a silicon substrate) and encapsulated inside a sensor package 208. The excitation coil 205 may include a conductive trace that is formed as part of a printed circuit board (PCB). The PCB may be provided separately from the sensor 201. The sensor package 208 may be formed by using an epoxy resin, a silicon gel, and/or any other suitable type of encapsulating compound. The sensing elements 202 may include one or more magnetic field sensing elements 202, such as giant magnetoresistance (GMR) elements, tunneling magnetoresistance sensing elements, Hall elements, fluxgate elements, and/or any other suitable type of magnetic field sensing elements. The processing circuitry 206 may include any suitable type of analog and/or digital circuitry for processing the output of sensing elements 202. By way of example, processing circuitry 206 may include one or more amplifiers, one or more digital-to-analog converters (DACs), one or more analog-to-digital converters (ADCs), one or more filters (analog or digital) and/or any other suitable processing circuitry that is normally found in magnetic field sensors. The excitation coil driver 204 may include any suitable type of processing circuitry for driving excitation coil 205. In some implementations, sensor 201 may be configured in the manner discussed in U.S. Patent Application 17/809,382 entitled Position Sensing Method, and U.S. Patent Application 18/354,895 entitled Position Sensing Method and System, both of which are hereby incorporated by reference herein in their entirety.

In operation, the sensing elements 202 may be configured to generate a sensing signal 203. The sensing signal 203 may be generated in response to a magnetic field sensed by the sensing elements 202. The sensing signal 203 may be indicative of the strength (e.g., magnetic flux density) of the magnetic field that is incident on sensing elements 202. The processing circuitry 206 may process signal 203 to generate an output signal 211. The output signal may be provided to electronic circuitry that is connected to the sensor 201. The output signal 211 may be indicative of the position of target 209 and it may be generated by using any method that is known to be employed by position sensors.

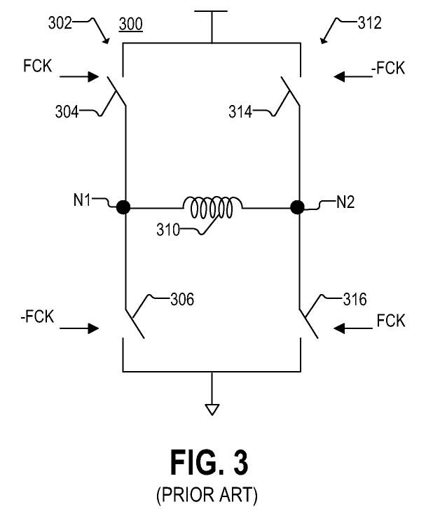

FIG. 3 is a diagram of a driver circuit 300, according to the prior art. In the example of FIG. 3, the driver circuit 300 is an H-bridge arranged to drive a coil 310. The driver circuit 300 may be the same or similar to any of coil drivers 104 and 204, and the coil 310 may be the same or similar to any of coils 105, 107, and 205. As illustrated, circuit 300 may include legs 302 and 312 that are coupled in parallel between a voltage source and ground. Leg 302 may include switches 304 and 306 that are coupled in series to each other at node N1. Leg 312 may include switches 314 and 314 that are coupled in series with each other at node N2. The coil 310 may be coupled between nodes N1 and N2, as shown. Each of switches 304, 306, 314, and 316 may include a metal-oxide semiconductor field-effect transistor (MOSFET). However, the present disclosure is not limited to any specific type of switch being used. Switches 304 and 316 may be opened and closed in accordance with a signal fck, and switches 306 and 314 may be opened and closed in accordance with the complement of signal fck. A disadvantage of circuit 300 is that it suffers from a limited power supply rejection ratio PSRR due to noise injected into the supply rails which is not fully rejected by the corresponding buffer circuits (if any). In addition, if the circuit 300 is driven under fast switching conditions (e.g., when signal fck has a high frequency component(s)), coil 310 would require the circuit 300 to develop a negative voltage (e.g., below ground) due to the signal fck having a high frequency (typically large dv/dts). Large dv/dt conditions generate among other things, parasitic capacitive currents that degrade the accuracy of the current being driven into de coil.

The discussion that follows provides examples of an improved circuit for driving a coil that lacks the drawbacks of circuit 300. FIGS. 1 and 2 are provided to illustrate that the improved circuit is not limited to being used in any specific sensor or for driving any specific type of coil. In this regard, it will be understood that the improved circuit can be used to drive any suitable type of coil, including, but not limited to, excitation coils that are used by position sensors and feedback coils that are used by magnetic field sensors in general.

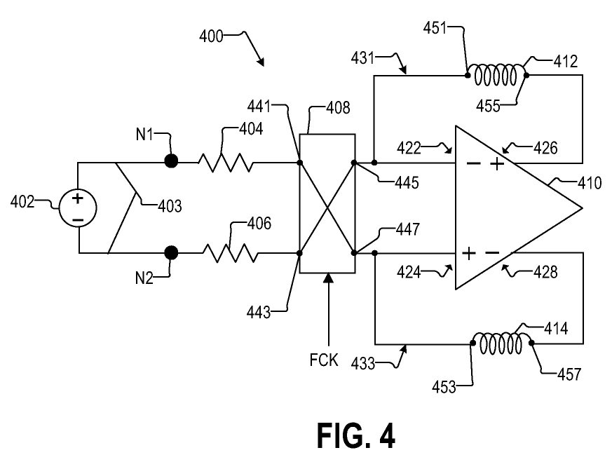

FIG. 4 is a diagram of an example of a coil driver 400, according to aspects of the disclosure.

In the example of FIG. 4, the coil driver 400 is arranged to drive coils 412 and 414. In some implementations, coils 412 and 414 may fulfill the same function as feedback coils 105 and 107, which is discussed above with respect to FIG. 1. Alternatively, coils 412 and 414 may together fulfill the same function as excitation coil 205, which is discussed above with respect to FIG. 2. Coils 412 and 414 may be implemented as conductive traces that are formed on a substrate (e.g., a semiconductor die or a PCB board) and/or in any other suitable manner. According to the present example, coils 412 and 414 are identical. However, alternative implementations are possible in which coils 412 and 414 are different from each other. For example, in some implementations, coil 412 may have a different number of turns (or lobes) than coil 414. As another example, the conductive trace (or wire) used to implement coil 412 may have a different thickness than the conductive trace that is used to implement coil 414. As another example, coils 412 and 414 may have different widths and/or lengths. As another example, coils 412 and 414 may have different radii. It will be understood that the present disclosure is not limited to any specific implementation of coils 412 and 414.

As illustrated, the coil driver 400 may be driven with a driving signal 403 which is applied at nodes N1 and N2 of the coil driver 400. According to the present example, signal 403 is provided, at least in part, by a constant voltage source 402. However alternative implementations are possible in which signal 403 is at least in part provided by a constant current source.

Additionally or alternatively, signal 403 be at least in part provided by a sensing bridge including one or more magnetic field sensing elements and/or any suitable type of circuitry that includes one or more magnetic field sensing elements. For example, signal 403 may be the same as, or otherwise derived from, the signal that is output on nodes 141 and 143 of the sensing bridge shown in FIG. 1B. When the signal 403 is generated at least in part based on the output of one or more magnetic field sensing elements, the level of signal 403 may vary with (or be indicative of) the magnetic field(s) that are incident on the magnetic field sensing elements used to generate the signal 403.

Additionally or alternatively, the signal applied at nodes N1 and N2 of the coil driver 400 (and/or input terminals 422 and 424 of amplifier 410) may be a sensing signal that is generated by one or more magnetic field sensing elements. The sensing signal may be generated in response to a magnetic field that is sensed by the one or more magnetic field sensing elements. The magnetic field sensing elements may be the same or similar to magnetic field sensing elements 102 (shown in FIG. 1A) or magnetic field sensing elements 202 (shown in FIG. 2). As used herein, the phrase “the sensing signal is applied at one or more input terminals of an amplifier” shall mean that either the sensing signal is applied directly at the input terminals or a signal that is generated, at least in part, based on the sensing signal is applied at the input terminals.

Coil driver 400 may include resistors 404 and 406, a modulator 408, and an amplifier 410. According to the present example, resistors 404 and 406 have the same resistance. However, in alternative implementations, resistors 404 and 406 may have different resistances. Modulator 408 may include cross-coupled switches, which are arranged to open and close at the frequency of a signal FCK. The cross-coupled switches may be configured to alternate the connectivity of each of the input terminals of modulator 408 (e.g., terminals 441 and 443) between the two output ports of modulator 408 (e.g., terminals 445 and 447). The amplifier 410 may be an operational amplifier. In some implementations, a diff-diff operational amplifier may be used, provided it is a balanced amplifier with a very high power supply rejection ratio (PSRR) (e.g., in the order of 60dB or higher). However, the present disclosure is not limited to using any specific type of amplifier, provided that the amplifier has a sufficiently high PSSR. In some implementations, the amplifier 410 may have an open loop gain in the range of +60db. This overall loop gain can be adjusted by changing the resistance of coils 412 and 414 and/or resistors 404 and 406.

The topology of coil driver 400 is now described in further detail. Resistor 404 may be coupled between node N1 and an input terminal 441 of modulator 408. Resistor 406 may be coupled between node N2 and an input terminal 443 of modulator 408. An output terminal 445 of modulator 408 may be coupled to an input terminal 422 of amplifier 410. An output terminal 447 of modulator 408 may be coupled to an input terminal 424 of amplifier 410. Coil 412 may be coupled between an output terminal 426 of amplifier 410 and input terminal 422 of amplifier 410. Coil 414 may be coupled between an output terminal 428 of amplifier 410 and input terminal 424 of amplifier 410. In the example of FIG. 4, input terminal 422 and output terminal 426 have opposite polarities. Similarly, terminals 424 and 428 also have opposite polarities. In this regard, coil 412 may be disposed in a negative feedback loop 431 of amplifier 410 and coil 414 may be disposed in a negative feedback loop 433 of amplifier 410.

The principle of operation of coil driver 400, in accordance with one example, is now described in further detail. In the example of FIG. 4, the amplifier 410 is operated in a diff-diff arrangement, whereby a reference input voltage (provided by voltage source 402) is used as input. This voltage is converted into a current by means of resistors 404 and 406. This converted current is injected into modulator 408 which will modulate the current to be injected into coils 412 and 414. The negative feedback loops 431 and 433 will have two currents with opposite directions and with the same amplitude. Thus, at any given time, the electrical current flowing through the negative feedback loop 431 may have a direction that is opposite to the direction of the electrical current flowing through negative feedback loop 433. Because amplifier 410 has a high gain, the arrangement whereby electrical current flows in opposite directions through negative feedback loops 431 and 433 results in a fixed voltage being forced on the coil terminals (e.g., coil terminals 451 and 453), which are connected to the inputs (e.g., input terminals 422 and 424) of amplifier 410. The outputs of amplifier 410 (e.g., output terminals 426 and 428), which are connected to the other coil terminals (e.g., terminals 455 and 457) will switch fast up and down in order to accommodate the current which is forced into the coils 412 and 414. Assuming the amplifier 410 has a high enough input impedance, most of the current will flow into the coils 412 and 414. In this way, the positive and negative excursions of the coils 414 and 412 will be around the common mode voltage of amplifier 410. The common mode voltage of amplifier 410 can be sized such that such excursions never go below ground, preventing the need for using a special device to allow an enhanced reverse of current flow. At the same time, the amplifier 410 being fully differential, significantly improves PSRR capabilities of the coil driver 400, since neither the positive nor the negative supply rails (not shown) of the voltage source 402 (or another power supply) are involved in the switching process of the currents flowing through the coils 412 and 414.

FIG. 4 is provided as an example only. The present disclosure is not limited to any specific implementation of coil driver 400. For example, in some implementations, modulator 408 may be omitted. As another example, resistors 406 and 404 can be omitted and voltage source 402 replaced with a current source. Additionally or alternatively, in some implementations, one or more additional electronic components may be positioned between node N1 and input terminal 422 of amplifier 410. Additionally or alternatively, in some implementations, one or more additional electronic components may be positioned between node N2 and input terminal 424 of amplifier 410. Additionally or alternatively, one or more additional electronic components may be included in any one of negative feedback loops 431 and 433. For example, to better control the closed loop gain, resonance frequency, and other characteristics of the coil driver 400, additional series resistors can be added in each (or at least one) of negative feedback loops 431 and 433. For example, one or more resistors may be coupled in series with coil 412 in the negative feedback loop 431, between input terminal 422 and output terminal 426 of amplifier 410. As another example, one or more resistors may be coupled in series with coil 414 in the negative feedback loop 433, between input terminal 424 and output terminal 428 of amplifier 410.

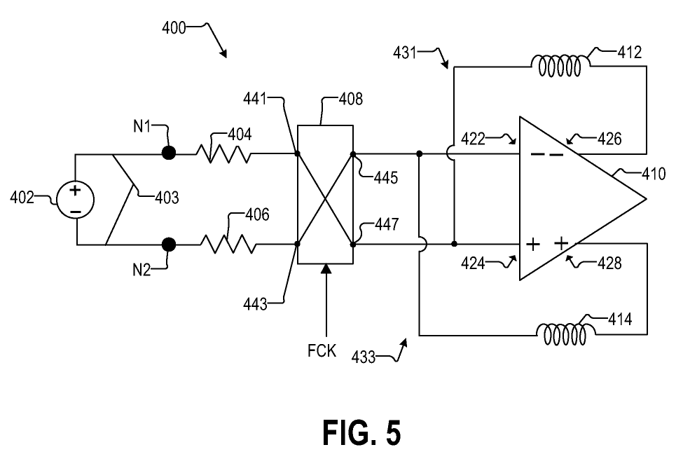

In the example of FIG. 4, amplifier 410 is an inverting amplifier. Specifically, the signal output on terminal 426 is an amplified inverted version of the signal that is applied at terminal 422, and the signal output on terminal 428 is an inverted amplified version of the signal applied at terminal 424. However, in alternative implementations, amplifier 410 may be a non-inverting amplifier. Specifically, FIG. 5 is a diagram of another example of the coil driver 400. The example of FIG. 5 is different from the example of FIG. 4 in that amplifier 410 is a non-inverting amplifier. Accordingly, terminal 426 is a non-inverting output that is arranged to output a non-inverted amplified copy of the signal applied at terminal 422, and terminal 428 is arranged to output a non-inverted amplified copy of the signal that is applied at terminal 424. In the example of FIG. 5, negative feedback loop 431 extends between terminals 424 and 426, and coil 412 is coupled in the negative feedback loop 431, as shown. Furthermore, in the example of FIG. 5, negative feedback loop 433 extends between terminals 428 and 422, and coil 414 is coupled in the negative feedback loop 433, as shown.

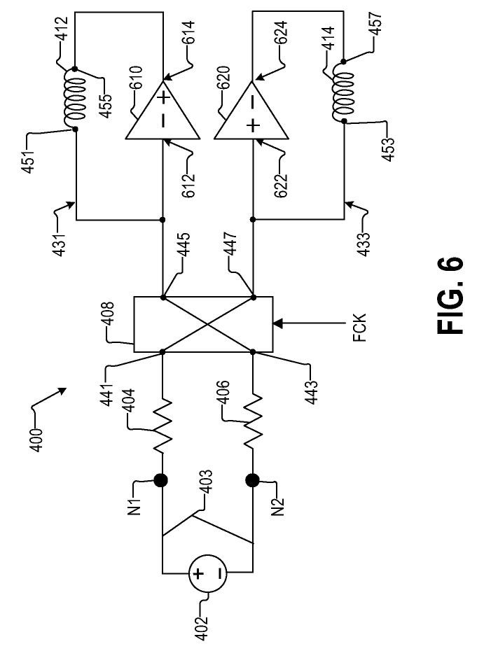

FIG. 6 is a diagram of yet another example of the coil driver 400, according to aspects of the disclosure. The implementation of coil driver 400 that is shown in FIG. 6 differs from the implementation shown in FIG. 4 in that amplifier 410 is replaced with amplifiers 610 and 620. Both amplifiers 610 and 620 are inverting amplifiers. Amplifier 610 may include an input terminal 612 and an output terminal 614. The negative feedback loop 431 may extend between the terminals 612 and 614 of amplifier 610, as shown. Amplifier 620 may include an input terminal 622 and an output terminal 624. The negative feedback loop 433 may extend between the terminals 622 and 624 of amplifier 620, as shown.

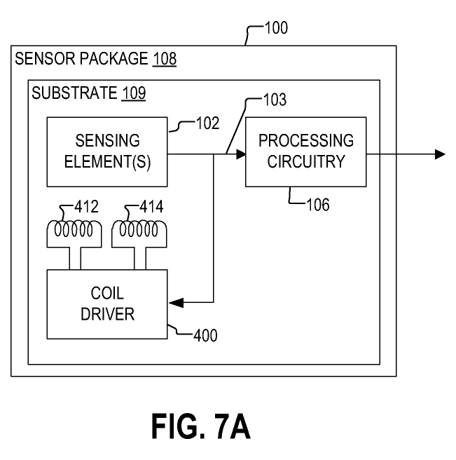

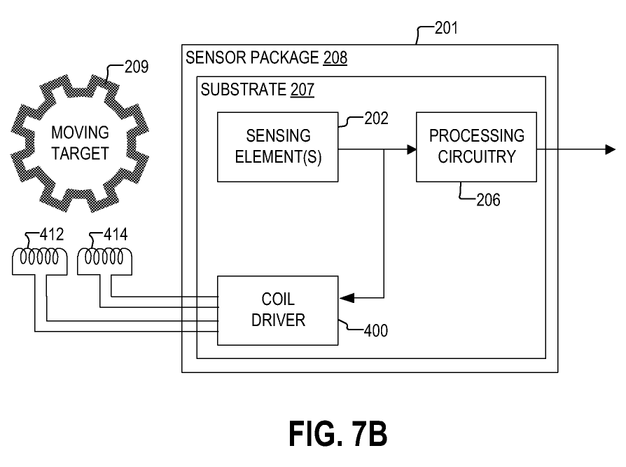

FIG. 7A is a schematic diagram of sensor 100 (also shown in FIG. 1A), according to aspects of the disclosure. The implementation of sensor 100 that is shown in FIG. 7A differs from the implementation shown in FIG. 1A in that: (1) the coil driver 104 is replaced with the coil driver 400, and (ii) the feedback coils 105 and 107 are replaced with coils 412 and 414. In the example of FIG. 7A, coils 412 and 414 are used to perform the same function as feedback coils 105 and 107. FIG. 7A is provided to illustrate that coil driver 400 may be integrated into existing sensor architectures by replacing what would be a conventional coil driver with the coil driver 400.

FIG. 7B is a schematic diagram of the sensor 201 (also shown in FIG. 2) in accordance with another example. The implementation of sensor 201 that is shown in FIG. 7B differs from the implementation shown in FIG. 2 in that: (1) the coil driver 204 is replaced with the coil driver 400, and (ii) the excitation coil 205 is replaced with coils 412 and 414. In the example of FIG. 7B, coils 412 and 414 are used together to perform the same function as coil 205. FIG. 7B is provided to illustrate that coil driver 400 may be integrated into existing sensor architectures by replacing what would be a conventional coil driver with the coil driver 400. Furthermore, FIG. 7B is provided to illustrate that coil driver 400 may be integrated into existing sensor architectures by replacing an individual excitation coil with a pair of different coils that are driven in the manner discussed with respect to FIGS. 4-6. As can be readily appreciated, one of the coils in the pair may be rotated so that the magnetic field that is produced by it would have the same direction as the magnetic field produced by the other coil.

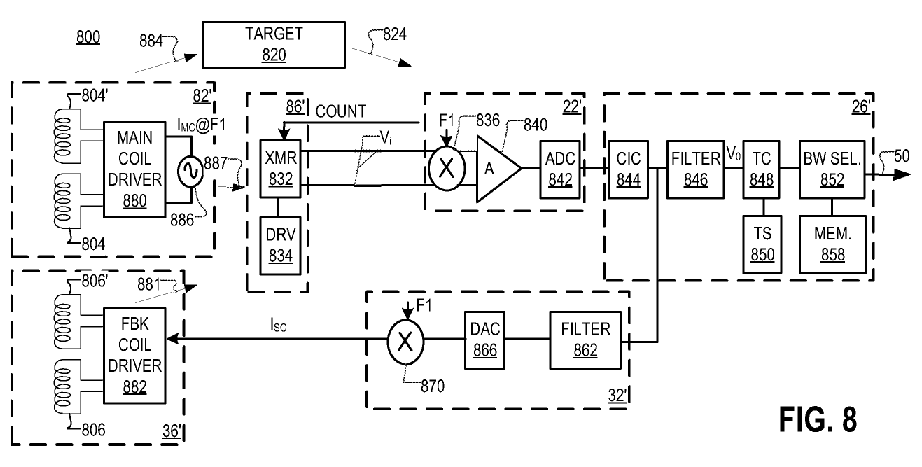

FIG. 8 is a diagram of a magnetic field sensor 800, according to aspects of the disclosure. The magnetic field sensor 800 includes main coil circuitry 82’, magnetoresistance circuitry 86’, analog circuitry 22’, digital circuitry 26’, feedback circuitry 32’, and secondary coil circuitry 36’.

In one example, the main coil circuitry 82’ may include main coils 804 and 804’, a coil driver circuit 880 and a source 886 (e.g., a current source or a voltage source). The source 886 provides an AC current I_{MC} at a first frequency F1. In one example, the first frequency F1 is between 1 and 8 MHz. In the present example the coil driver circuit 880 may be the same or similar to the coil driver 400, which is discussed above with respect to FIGS. 4-6, and the coils 804 and 804’ may be the same or similar to the feedback coils 412 and 414, which are also discussed above with respect to FIGS. 4-6.

The current I_{MC} enables the coil driver circuit 880 to power the main coils 804 and 804’ to generate a magnetic field signal 884. In one example, the main coils 804 and 804’ have a coupling factor K_{MC} of 60 Gauss per amp.

In one example, the magnetoresistance circuitry 86’ includes a sensing bridge 832 and a driver 834 that drives the sensing bridge 832. The sensing bridge 832 may receive a magnetic-field error signal 887, which is converted into a differential output voltage signal called herein an error signal Vᵢ. Under the nomenclature of the present disclosure, the signal Vi is called an error signal because it carries an error, but it can also be thought of as the raw output of sensing bridge 832. In other words, signal Vi may be thought of as the result of the magnetic error signal, generated as the difference between the sum of the magnetic field generated by the main coil 804 and the reflected field from target 820, minus the feedback coil field. Ideally this subtraction should yield zero if the loop had infinite loop gain. Since realistic loops have finite (although large) gains, the error signal will not be zero, although very small. The sensing bridge 832 may be a half-bridge or a full bridge (e.g., a Wheatstone bridge circuit). According to the present example, the sensing bridge 832 includes a plurality of tunneling magnetoresistance elements (TMRs). However, the present disclosure is not limited to any specific type of sensing element being included in the sensing bridge 832.

In one example, the analog circuitry 22’ may include a mixer 836, an amplifier 840, and an analog-to-digital converter (ADC) 842.

The mixer 836 receives the error signal Vᵢ from the magnetoresistance circuitry 86’ and demodulates the error signal Vᵢ with the first frequency F1 to form a baseband signal. The baseband signal is amplified by the amplifier 840 by a gain A. The amplified baseband signal is converted from an analog signal to a digital signal by the ADC 842. In one example, the ADC 842 may be a sigma-delta ADC.

In one example, the digital circuitry 26’ may include a cascaded integrator-comb (CIC) filter 844, a filter 846, a temperature correction circuit 848, a temperature sensor 850, a bandwidth (BW) selection circuit 852, and a programming and memory circuit 858.

The CIC filter 844 receives the digital baseband signal from the ADC 842. The filter 846 may be a low pass filter configured to filter noise and other artifacts from output of the CIC filter 844 to produce an output voltage signal Vₒ. The temperature correction circuit 848 may scale the output voltage signal Vₒ according to temperature (e.g., a temperature measured by the temperature sensor 850). The BW selection circuit 852 provides a further low-pass filtering with a selectable cut-off frequency to generate the output signal 50.

In one example, the feedback circuitry 32’ includes a filter 862, a digital-to analog converter (DAC) 866 and a mixer 870. The filter 862 may be a low pass filter configured to filter noise and other artifacts from output of the CIC filter 844. The DAC 866 receives the filtered digital output signal from the filter 862 and converts the filtered digital output signal from a digital voltage signal to an analog current signal. The analog current signal from the DAC 866 is provided to a mixer 870. The mixer 870 mixes the analog current signal with the first frequency F1 to form an AC current signal I_{SC} to enable the secondary coil driver circuit 882 to drive the secondary coils 806 and 806’.

In one example, the secondary coil circuitry 36’ includes a secondary coil 806 and a secondary coil driver circuit 882. The AC current signal I_{SC} enables the secondary coil driver circuit 882 to power the secondary coils 806 and 806’ to produce the magnetic field signal 881. In one example, the secondary coils 806 and 806’ have a coupling factor K_{SC} of 800 Gauss per amp. In the present example the secondary coil driver circuit 882 may be the same or similar to the coil driver 400, which is discussed above with respect to FIGS. 4-6, and the coils 806 and 806’ may be the same or similar to the feedback coils 412 and 412, which are also discussed above with respect to FIGS. 4-6.

The magnetic field signal 884 is combined with the reflected field signal 824, and also any signal directly coupled from the main coils 804 and 804’ to sensing bridge 832, at a medium to form the magnetic-field error signal 887. The medium may be air. The medium may not be on the magnetic field sensor 800.

As noted above, the signal Vi is generated in response to the signal 887. The secondary coil circuitry 36’ may be used to remove, or ideally eliminate, the amount of error that is present in the signal Vi. Specifically, the non-linear behavior of the TMRs in sensing bridge 832 is masked by the magnetic-field closed-loop approach and the overall system gain does not depend on the sensitivity of any of the TMRs in sensing bridge 832. The secondary coils 806 and 806’ compensate for reflected fields from the target 820 and keeps the TMRs in sensing bridge 832 element at an operating point at or near zero Gauss. In some implementations, target 820 may be a rotating target, in which case the signal output from sensing bridge 832 may be an alternating current (AC) signal.

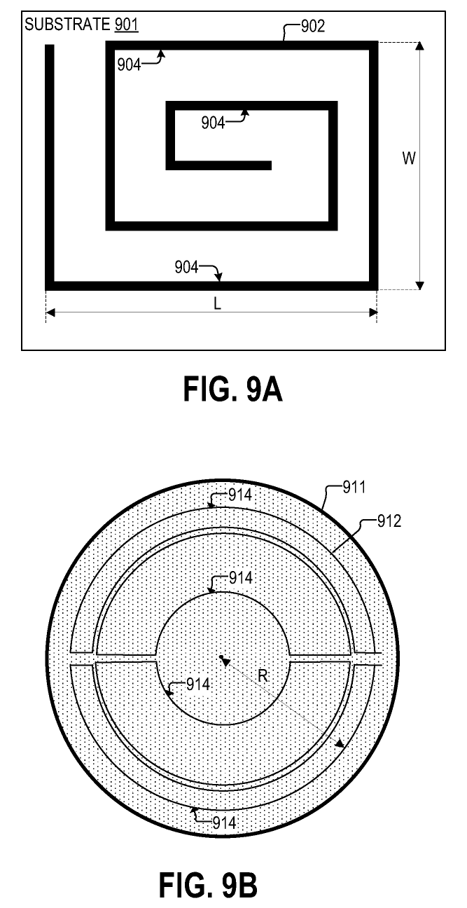

FIG. 9A is a schematic diagram of an example of a coil 902. In the example of FIG. 9A, coil 902 is implemented as a conductive trace that is formed on a substrate 901. The coil 902 may include a plurality of turns 904, and it may have a width W and length L. The substrate 901 may be the same or similar to the substrate 109, which is discussed above with respect to FIG. 1A. For example, the substrate 901 may include a sensor die, such as a silicon die, which has all (or at least some) of the components of a magnetic field sensor formed on it. In some implementations, coil 902 may be the same or similar to coils 412 and 414, which are discussed above with respect to FIGS. 4-6. FIG. 9A is provided to illustrate one possible example of a coil that can be integrated, together with coil driver 400, inside the packaging of a magnetic field sensor.

FIG. 9B is a schematic diagram of an example of a coil 912. In the example of FIG. 9A, coil 912 is implemented as a conductive trace that is formed on a substrate 911. The coil 912 may include a plurality of lobes 914, and it may have a radius R. According to the present example, the substrate 911 is a printed circuit board. In some implementations, coil 912 may be the same or similar to coils 412 and 414, which are discussed above with respect to FIGS. 4-6. FIG. 9B is provided to illustrate one possible example of a coil that can be provided externally from a magnetic field sensor that includes the coil driver 400.

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. Throughout the disclosure, like numerals refer to like elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
one or more magnetic field sensing elements that are configured to generate a sensing signal, the sensing signal being indicative of a strength of a magnetic field that is incident on the one or more magnetic field sensing elements;
a processing circuitry that is configured to generate an output signal based on the sensing signal; and
an amplifier that is configured to drive a first coil and a second coil based on the sensing signal, the first coil being coupled in a first negative feedback loop of the amplifier, and the second coil being coupled in a second negative feedback loop of the amplifier,
wherein the first negative feedback loop spans between a first input terminal of the amplifier and a first output terminal of the amplifier, and the second negative feedback loop spans between a second input terminal of the amplifier and a second output terminal of the amplifier, and
wherein the sensing signal is applied at the first and second input terminals of the amplifier.

2. The sensor of claim 1, wherein the first and second output terminals are non-inverting output terminals.

3. The sensor of claim 1, wherein the first and second output terminals are inverting output terminals.

4. The sensor of claim 1, wherein the first and second coils are excitation coils that are arranged to excite a moving target, and the magnetic field is a reflected magnetic field.

5. The sensor of claim 1, wherein the first and second coils are feedback coils.

6. The sensor of claim 1, wherein the sensor includes one of a position sensor or a current sensor.

7. The sensor of claim 1, wherein each of the one or more magnetic field sensing elements includes one of a giant magnetoresistance (GMR) element, a tunnelling magnetoresistance (TMR) element, a magnetic tunnel junction (MTJ) element, a Hall element, or a fluxgate element.

8. The sensor of claim 1, wherein the first coil and the second coil are different from each other.

9. The sensor of claim 1, wherein the first coil includes a different number of turns than the second coil.

10. The sensor of claim 1, wherein the first coil includes a different number lobes than the second coil.

11. The sensor of claim 1, wherein the first and second coil are encapsulated in a same semiconductor package with the one or more magnetic field sensing elements, the processing circuitry, and the amplifier.

12. The sensor of claim 1, wherein one or more magnetic field sensing elements, the amplifier, and the processing circuitry are encapsulated in a semiconductor package and the first and second coils are external to the semiconductor package.

13. A sensor, comprising:
one or more magnetic field sensing elements that are configured to generate a sensing signal, the sensing signal being indicative of a strength of a magnetic field that is incident on the one or more magnetic field sensing elements;
a processing circuitry that is configured to generate an output signal based on the sensing signal; and
a first amplifier that is configured to drive a first coil based on the sensing signal, the first coil being coupled in a first negative feedback loop of the first amplifier,
wherein the first negative feedback loop spans between a first input terminal of the first amplifier and a first output terminal of the first amplifier, and
wherein the sensing signal is, at least in part, applied at the first input terminals of the first amplifier.

14. The sensor of claim 13, wherein the first amplifier is configured to drive a second coil that is coupled in a second negative feedback loop of the first amplifier, the second negative feedback loop spanning between a second input terminal of the first amplifier and a second output terminal of the first amplifier, the sensing signal being applied, at least in part, at the second input terminal of the first amplifier.

15. The sensor of claim 13 further comprising a second amplifier configured to drive a second coil that is coupled in a second feedback loop of the second amplifier, the second feedback loop spanning between a second input terminal of the second amplifier and a second output terminal of the second amplifier, the sensing signal being applied, at least in part, at the second input terminal of the second amplifier.

16. The sensor of claim 13, wherein the first output terminal includes an inverting output terminal.

17. The sensor of claim 13, wherein the first coil is arranged to excite a moving target, and the magnetic field is a reflected magnetic field.

18. The sensor of claim 13, wherein the first coil is a feedback coil.

19. The sensor of claim 13, wherein the sensor includes one of a position sensor or a current sensor.

20. The sensor of claim 13, wherein each of the one or more magnetic field sensing elements includes one of a giant magnetoresistance (GMR) element, a tunnelling magnetoresistance (TMR) element, a magnetic tunnel junction (MTJ) element, a Hall element, or a fluxgate element.

21. The sensor of claim 14, wherein the first coil and the second coil are different from each other.

22. The sensor of claim 14, wherein the first coil includes a different number of turns than the second coil.

23. The sensor of claim 14, wherein the first coil includes a different number lobes than the second coil.

24. A sensor, comprising:
one or more magnetic field sensing elements that are configured to generate a sensing signal, the sensing signal being indicative of a strength of a magnetic field that is incident on the one or more magnetic field sensing elements;
a processing circuitry that is configured to generate an output signal based on the sensing signal; and
a first amplifier that is configured to drive a first coil based on the sensing signal, the first coil being coupled in a first negative feedback loop of the first amplifier,
wherein the first negative feedback loop spans between a first input terminal of the first amplifier and a first output terminal of the first amplifier.

25. The sensor of claim 24, wherein the first coil includes an excitation coil configured to cause a moving target to generate the magnetic field.

26. The sensor of claim 24, wherein the first coil includes a feedback coil configured to configured to generate a feedback magnetic field that is applied to at least one of the magnetic field sensing elements.

27. The sensor of claim 24, wherein the first amplifier is driven with the sensing signal, the sensing signal being applied, at least in part, at the first input terminal of the first amplifier.

28. The sensor of claim 24, wherein the first amplifier is configured to drive a second coil that is coupled in a second negative feedback loop of the first amplifier, the second negative feedback loop spanning between a second input terminal of the first amplifier and a second output terminal of the first amplifier.

29. The sensor of claim 24, further comprising a second amplifier configured to drive a second coil that is coupled in a second feedback loop of the second amplifier, the second feedback loop spanning between a second input terminal of the second amplifier and a second output terminal of the second amplifier.

30. The sensor of claim 24, wherein the first output terminal includes an inverting output terminal.

31. The sensor of claim 24, wherein each of the one or more magnetic field sensing elements includes one of a giant magnetoresistance (GMR) element, a tunnelling magnetoresistance (TMR) element, a magnetic tunnel junction (MTJ) element, a Hall element, or a fluxgate element.

32. The sensor of claim 24, wherein the amplifier is first driver with a driving signal that is generated by a power source, the driving signal being generated independently of the one or more magnetic field sensing elements, the driving signal being applied, at least in part, at the first input terminal of the first amplifier.
